(19) United States
(12) Patent Application Publication
(10) Pub. No.: US 2021/0027833 A1
(43) Pub. Date: Jan. 28, 2021

(54) 8T STATIC RANDOM ACCESS MEMORY

(71) Applicants: MASUD H. CHOWDHURY, LEE'S SUMMIT, MO (US); MAHMOOD UDDIN MOHAMMED, KANSAS CITY, MO (US); NAHID M. HOSSAIN, SANTA CLARA, CA (US)

(72) Inventors: MASUD H. CHOWDHURY, LEE'S SUMMIT, MO (US); MAHMOOD UDDIN MOHAMMED, KANSAS CITY, MO (US); NAHID M. HOSSAIN, SANTA CLARA, CA (US)

(21) Appl. No.: 16/634,655

(22) PCT Filed: Jul. 30, 2018
(86) PCT No.: PCT/US2018/044336

§ 371 Date: Jan. 28, 2020

Related U.S. Application Data
(60) Provisional application No. 62/538,012, filed on Jul. 28, 2017.

(51) Int. Cl. G11C 11/412; G11C 11/418; G11C 11/419

(52) U.S. Cl. CPC G11C 11/412; G11C 11/419; G11C 11/418

(57) ABSTRACT

An 8-transistor (8T) static random access memory (SRAM) cell is provided. The SRAM cell includes a first inverter and a second inverter that are cross-coupled to define first and second storage nodes. The SRAM cell also includes a first access transistor controlled by a write word line, wherein the first access transistor is configured to couple the first storage node to a write bit line when the write word line is activated. The SRAM cell further includes a second access transistor controlled by a read word line, wherein the second access transistor is configured to couple the second storage node to the read bit line through a third inverter when the read word line is activated. The third inverter is configured to charge the read bit line so that a pre-charging circuit is not required. In the SRAM cell, the reading and writing operations are electrically separated to lower power consumption, improve noise margin, and provide other advantages compared to existing SRAM cell designs.

### CROSS-REFERENCE TO RELATED APPLICATIONS

This application is based on and claims priority to U.S. Provisional Application Ser. No. 62/538,012, filed on Jul. 28, 2017, which is incorporated herein by reference in its entirety.

### BACKGROUND OF THE INVENTION

Low power design has become increasingly important for diverse applications due to the growing demands for more functionality at higher energy efficiency, particularly in mobile and wireless devices. With the increase in required memory capacity and density, it has become critical to ensure lower power consumption and higher speed of the memory cells and blocks because overall system performance is heavily dependent on the memory. Various techniques have been employed to reduce power consumption and improve noise margin in memory design, such as circuit partitioning, dual threshold voltage schemes, increasing the thickness of the gate oxide for noncritical circuits, and many more. However, there remains a need for improved memory cells that lower power consumption, improve noise margin, and offer other advantages compared to existing memory cells.

### BRIEF SUMMARY OF THE INVENTION

The present invention is directed to an 8-transistor (8T) static random access memory (SRAM) cell in which the reading and writing operations are electrically separated to lower power consumption, improve noise margin, and provide other advantages compared to existing SRAM cell designs.

In one embodiment, the SRAM cell includes a first inverter comprising a first pull-up transistor and a first pull-down transistor, and, a second inverter comprising a second pull-up transistor and a second pull-down transistor. The output node of the first inverter is coupled to the input node of the second inverter to define a first storage node, and the input node of the first inverter is coupled to the output node of the second inverter to define a second storage node. The cell also includes a third inverter configured to charge a read bit line so that a pre-charging circuit is not required.

The SRAM cell also includes a first access transistor controlled by a write word line. The first access transistor is configured to couple the first storage node to a write bit line when the write word line is activated, and, decouple the first storage node from the write bit line when the write word line is deactivated. The first and second inverters and the first access transistor form a write circuit that is electrically separated from the second access transistor and the third inverter during a write operation. Only one word line (i.e., the write word line) and only one bit line (i.e., the write bit line) are utilized during the write operation. The cell is configured to perform the write operation when (i) the write word line is activated so as to turn on the first access transistor and couple the first storage node to the write bit line and (ii) the read word line is deactivated so as to turn off the second access transistor and decouple the second storage node from the third inverter and the read bit line. Moreover, the write operation preferably utilizes a virtual ground circuit that weakens the positive feedback of the first and second inverters and improves the write ability of the cell.

The SRAM cell further includes a second access transistor controlled by a read word line. The second access transistor is configured to couple the second storage node to the read bit line through the third inverter when the read word line is activated, and, decouple the second storage node from the third inverter and the read bit line when the read word line is deactivated. The first and second inverters, the second access transistor, and the third inverter form a read circuit that is electrically separated from the first access transistor during a read operation. Only one word line (i.e., the read word line) and only one bit line (i.e., the read bit line) are utilized during the read operation. The cell is configured to perform the read operation when (i) the read word line is activated so as to turn on the second access transistor and couple the second storage node to the read bit line through the third inverter and (ii) the write word line is deactivated so as to turn off the first access transistor and decouple the first storage node from the write bit line.

In another embodiment, the SRAM cell includes a first inverter and a second inverter each of which comprises a p-type MOS (PMOS) transistor and an n-type MOS (NMOS) transistor, wherein the first and second inverters are cross-coupled to define first and second storage nodes. The cell also includes a third inverter comprising a PMOS transistor and an NMOS transistor, which is configured to charge a read bit line so that a pre-charging circuit is not required.

The SRAM cell also includes a first access transistor comprising an NMOS transistor that is controlled by a write word line. The first access transistor is configured to couple the first storage node to a write bit line when the write word line is activated, and, decouple the first storage node from the write bit line when the write word line is deactivated. Only one word line (i.e., the write word line) and only one bit line (i.e., the write bit line) are utilized during a write operation. The cell is configured to perform the write operation when (i) the write word line is activated so as to turn on the first access transistor and couple the first storage node to the write bit line and (ii) the read word line is deactivated so as to turn off the second access transistor and decouple the read bit line. Moreover, the write operation preferably utilizes a virtual ground circuit that weakens the positive feedback of the first and second inverters and improves the write ability of the cell.

The SRAM cell further includes a second access transistor comprising an NMOS transistor that is controlled by a read word line. The second access transistor is configured to couple the output of the third inverter to the read bit line when the read word line is activated. The design utilizes a single-ended bit line for separate read and write operations, which eventually reduces delay and power consumption during the read and write operations. Only one word line (i.e., the read word line) and only one bit line (i.e., the read bit line) are utilized during the read operation. The cell is configured to perform the read operation when (i) the read word line is activated so as to turn on the second access transistor and couple the output of the third inverter to the read bit line and (ii) the write word line is deactivated so as to turn off the first access transistor and decouple the first storage node from the write bit line.

In yet another embodiment, the SRAM cell includes a first inverter and a second inverter that define first and second storage nodes. The cell also includes a third inverter configured to charge a read bit line so that a pre-charging circuit is not required.

The SRAM cell also includes a first access transistor controlled by a single write word line. The first access transistor is configured to couple the first storage node to a single write bit line when the write word line is activated. The cell is configured to perform the write operation when (i) the write word line is activated so as to turn on the first access transistor and couple the first storage node to the write bit line and (ii) the read word line is deactivated so as to turn off the second access transistor and decouple the second storage node through the third inverter from the read bit line.

The SRAM cell further includes a second access transistor controlled by a single read word line. The second access transistor is configured to couple the second storage node to the single read bit line through the third inverter when the read word line is activated. The cell is configured to perform the read operation when (i) the read word line is activated so as to turn on the second access transistor and couple the second storage node to the read bit line through the third inverter and (ii) the write word line is deactivated so as to turn off the first access transistor and decouple the first storage node from the write bit line.

### BRIEF DESCRIPTION OF THE DRAWINGS

The present invention will be described in detail below with reference to the attached drawing figures, wherein:

FIG. 1 is a diagram of a conventional 6T SRAM cell circuit;

FIG. 2 is a diagram of a conventional 8T SRAM cell circuit;

FIG. 3 is a diagram of an existing 9T SRAM cell circuit;

FIG. 4 is a diagram of an existing 10T SRAM cell circuit;

FIG. 5 is a diagram of an 8T SRAM cell circuit in accordance with a first embodiment of the present invention;

FIG. 6 is a diagram of the virtual ground circuit used in connection with the 8T SRAM cell shown in FIG. 5 during a write operation;

FIG. 7 is a plot showing the voltages of the write word line (WWL), the write bit line (WBL), and the two storage nodes (Q and QB) of the 8T SRAM cell circuit shown in FIG. 5 during a write operation;

FIG. 8 is a diagram of an exemplary memory system architecture of the 8T SRAM cell circuit shown in FIG. 5;

FIG. 9 is a plot showing the voltages of the read word line (RWL), the read bit line (RBL) and the two storage nodes (Q and QB) of the 8T SRAM cell circuit shown in FIG. 5 during a read operation;

FIG. 10 is diagram of the layout of the 8T SRAM cell circuit shown in FIG. 5 implemented using 45 nm technology node;

FIG. 11 is a plot comparing the hold static noise margin (HSNM) of the 8T SRAM cell circuit shown in FIG. 5, conventional 6T SRAM cell circuit shown in FIG. 1 and conventional 8T SRAM cell circuit shown in FIG. 2 for a 1V supply voltage;

FIG. 12 is a plot showing the read static noise margin (RSNM) of the 8T SRAM cell circuit shown in FIG. 5, conventional 6T SRAM cell circuit shown in FIG. 1 and conventional 8T SRAM cell circuit shown in FIG. 2 for a 1V supply voltage;

FIG. 13 is a plot showing the write static noise margin (WSNM) of the 8T SRAM cell circuit shown in FIG. 5, conventional 6T SRAM cell circuit shown in FIG. 1 and conventional 8T SRAM cell circuit shown in FIG. 2 for a 1V supply voltage;

FIG. 14 is a plot showing the N-curve of the 8T SRAM cell circuit shown in FIG. 5;

FIG. 15 is a plot showing the read static noise margin analysis of the 8T SRAM cell circuit shown in FIG. 5, conventional 6T SRAM cell circuit shown in FIG. 1 and conventional 8T SRAM cell circuit shown in FIG. 2 at different process corners for a 0.4V supply voltage;

FIG. 16 is a plot showing the variation of stability with temperature for the 8T SRAM cell circuit shown in FIG. 5, conventional 6T SRAM cell circuit shown in FIG. 1 and conventional 8T SRAM cell circuit shown in FIG. 2;

FIGS. 17A and 17B are plots showing the Monte Carlo analysis result for a Vₜₕ variation of the 8T SRAM cell circuit shown in FIG. 5 during read;

FIGS. 18A and 18B are plots showing the Monte Carlo analysis result for a Vₜₕ variation of the 8T SRAM cell circuit shown in FIG. 5 during read;

FIG. 19 is a plot showing the transient response of a 1Kb 8T SRAM array; and

FIG. 20 is a diagram of an 8T SRAM cell circuit in accordance with an alternative embodiment of the present invention.

### DETAILED DESCRIPTION OF EXEMPLARY EMBODIMENTS OF THE INVENTION

The present invention is directed to an 8-transistor (8T) static random access memory (SRAM) cell in which the reading and writing operations are electrically separated to lower power consumption, improve noise margin, and provide other advantages compared to existing SRAM cell designs. While the invention will be described in detail below with reference to various embodiments, it should be understood that the invention is not limited to the specific structural configuration or operation of these embodiments. In addition, although the embodiments are described as embodying several different inventive features, one skilled in the art will appreciate that any one of these features could be implemented without the others in accordance with the present invention.

I. Existing SRAM Cell Designs

As described in greater detail below, the 8T SRAM cell circuit of the present invention provides a variety of advantages compared to existing SRAM cell designs that use between 6 and 10 transistors per cell, i.e., 6T, 7T, 8T, 9T and 10T SRAM cells. In order to better understand these advantages, the designs of several existing SRAM cells are generally described below.

A. Conventional 6T SRAM Cell

FIG. 1 shows a conventional 6T SRAM cell circuit. The circuit includes a storage cell comprising four transistors P1, P2, N1 and N2 that form two inverters P1-N1 and P2-N2. Transistors P1 and P2 comprise PMOS transistors that function as pull-up transistors, and transistors N1 and N2 comprise NMOS transistors that function as pull-down transistors. Transistors P1 and N1 are connected in series between the supply voltage V_{dd} and ground and, similarly, transistors P2 and N2 are connected in series between the supply voltage V_{dd} and ground. The input and output terminals of inverters P1-N1 and P2-N2 are cross-coupled such that the output node of inverter P1-N1 is coupled to the input node of inverter P2-N2 to define a first storage node Q and the input node of inverter P1-N1 is coupled to the output node of inverter P2-N2 to define a second storage node QB. The bit stored in the storage cell is accessible via storage nodes Q and QB. Thus, if a “0” is stored in the storage cell, storage node Q is logic low and storage node QB is logic high (i.e., Q=0 and QB=1). If a “1” is stored in the storage cell, storage node Q is logic high and storage node QB is logic low (i.e., Q=1 and QB=0).

The circuit also includes two access transistors N3 and N4 that are controlled by a word line WL. Access transistor N3 is an NMOS transistor that functions as a transfer gate between storage node Q and a bit line BL. Similarly, access transistor N4 is an NMOS transistor that functions as a transfer gate between storage node QB and a bit line BLB. When word line WL is activated, access transistors N3 and N4 are turned on so as to couple storage nodes Q and QB to bit lines BL and BLB, respectively. However, when word line WL is deactivated, access transistors N3 and N4 are turned off so as to decouple storage nodes Q and QB from bit lines BL and BLB, respectively.

The circuit operates in one of three possible modes: a hold mold, a reading mode and a writing mode. In the hold mold, word line WL is deactivated (i.e., WL=0) so as to decouple storage nodes Q and QB from bit lines BL and BLB, respectively, and thereby hold the current bit in the storage cell. In the reading mode, bit lines BL and BLB are pre-charged and then word line WL is activated (i.e., WL=1) so as to enable a determination of the current bit stored in the storage cell. The operation of the circuit during a read operation is well-known in the art and will not be further described herein. In the writing mode, bit lines BL and BLB are driven to the required state and word line is activated (i.e., WL=1) so as to write the new bit to the storage cell. The operation of the circuit during a write operation is well-known in the art and will not be further described herein.

It can be seen that the circuit is area efficient due to its simplicity and the symmetry of the transistors. However, the transistors must be properly sized to avoid read upsets, i.e., the design requires strict sizing ratios to avoid accidental writing of a “1” into the storage cell during a read “0” operation. For example, if one were to design the circuit using 90 nanometer (90 nm) technology node, the size of pull-up transistors P1 and P2 could be 90 nm, but the sizes of pull-down transistors N1 and N2 and access transistors N3 and N4 would have to be several times larger than 90 nm to satisfy the size restrictions related to the cell ratio (CR) and the pull-up ratio (PR) of the circuit. Another problem is that the circuit cannot operate in the subthreshold region because of process variation and reduced voltage level. Therefore, the circuit is not suitable for ultra-low-power circuits that operate in the subthreshold region.

B. Conventional 8T SRAM Cell

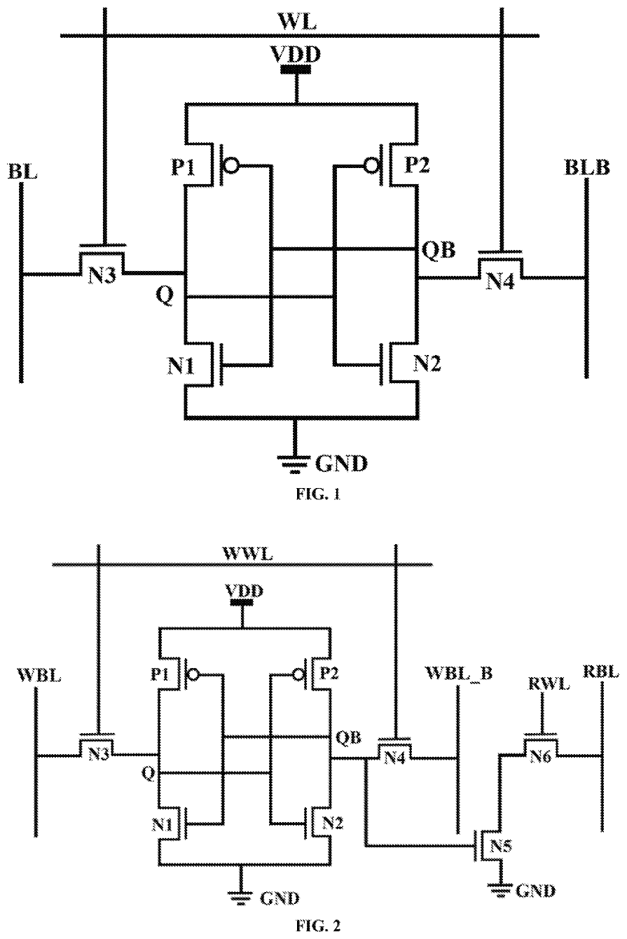

FIG. 2 shows a conventional 8T SRAM cell circuit. The circuit is similar to the 6T SRAM cell circuit shown in FIG. 1 with the following differences. First, the circuit includes a write word line WWL and two write bit lines WBL and WBL_B, as well as a read word line RWL and a read bit line RBL. Second, the circuit includes two read stack transistors N5 and N6 (both of which comprise NMOS transistors) that are connected in series between storage node QB and read bit line RBL. In this circuit, the read operation is separated from the rest of the cell, which increases the read static noise margin (RSNM) so as to ensure better read stability and robustness. The read stability can be further improved by increasing the size of read stack transistors N5 and N6. In contrast, to improve the read stability of the 6T SRAM cell circuit, all six of the transistors must be enlarged. Of course, the design of this circuit still requires sizing ratios and a pre-charging circuit for read bit line RBL and, in addition, the write operation is similar to that of the 6T SRAM cell circuit.

C. 9T SF-SRAM Cell

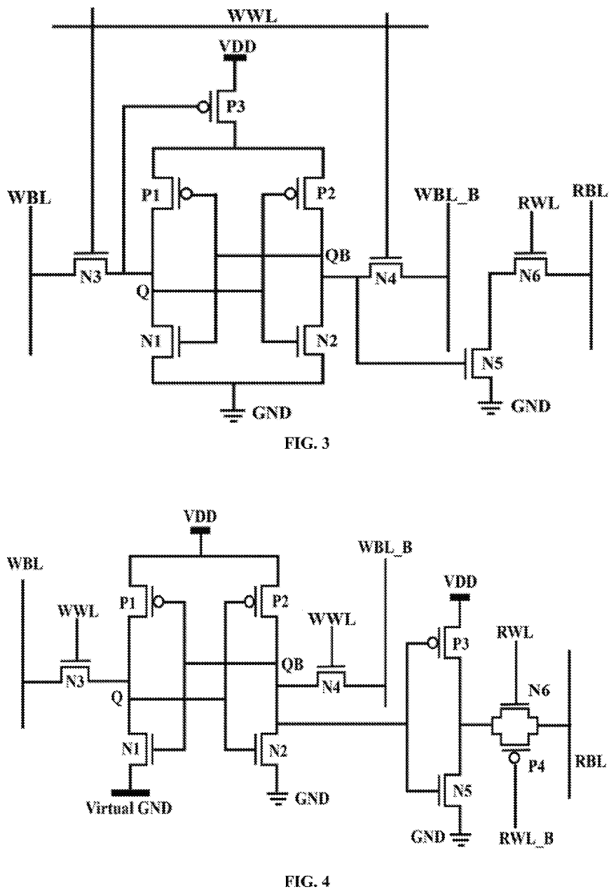

There are several existing designs that utilize 9 transistors per cell—one type is the 9T supply-feedback (SF) SRAM cell circuit shown in FIG. 3. The circuit is similar to the 8T SRAM cell circuit shown in FIG. 2 with the addition of a supply gating transistor P3 (comprising a PMOS transistor) that is connected in the feedback loop with storage node Q. Supply gating transistor P3 increases the write ability by weakening the pull-up path and enabling the data to be flipped more easily during the write operation. It should be noted that the internal gating generates a small voltage drop at the drain of supply gating transistor P3 during the hold mode, which results in lower leakage currents at the expense of a reduction in the hold static noise margin (HSNM). Also, the extra supply gating transistor P3 increases the area overhead, reading time and power consumption. In addition, the asymmetric circuit construction increases the complexity and area overhead of the circuit. Further, the design of this circuit still requires a pre-charging circuit for read bit line RBL.

D. 10T Single-Ended SRAM Cell

FIG. 4 shows an existing 10T single-ended SRAM cell circuit. The circuit is similar to the 8T SRAM cell circuit shown in FIG. 2 with the exception that read stack transistors N5 and N6 of the 8T SRAM cell circuit are replaced with the following: (i) an inverter P3-N5 that includes a pull-up transistor P3 (comprising a PMOS transistor) connected in series with a pull-down transistor N5 (comprising an NMOS transistor) between the supply voltage V_{dd} and ground and (ii) a transmission gate that includes transistors N6 (comprising an NMOS transistor) and P4 (comprising an PMOS transistor) connected in parallel. There are two read word lines in which read word line RWL controls transistor N6 at the transmission gate and read word line RWL_B controls transistor P4 at the transmission gate. When the read word lines are activated (i.e., RWL=1 and RWL_B=1), the transmission gate is triggered and storage node QB is coupled to the read bit line RBL through the inverter P3-N5. There are also two write word lines WWL and WWL_B.

In this circuit, a pre-charging circuit is not required because the inverter P3-N5 fully charges/discharges the read bit line RBL. The charge and discharge powers are only consumed if the readout data is different from the previous state. Therefore, the cell consumes no additional power if consecutive 0's or 1's are read out from the storage cell over the read bit line RBL. The transient probability on the read bit line RBL is 50% in a sequence of random data, thereby reducing power consumption significantly during the read operation. In contrast, the existing 6T, 8T and 9T SRAM cell circuits described above require pre-charging of the bit lines during the read operation, which imposes energy and timing constraints on the design and operation of high-density and high-capacity SRAM applications. Of course, the 10T single-ended SRAM cell circuit requires additional devices and wirings that impose higher area overheads compared to the existing 6T, 8T and 9T SRAM cell circuits.

II. New 8T SRAM Cell Circuit

The 8T SRAM cell circuit of the present invention (which may be referred as the “new” 8T SRAM cell circuit in order to distinguish it from the existing 8T SRAM cell circuit described above) provides a variety of advantages compared to existing SRAM cell designs. In order to illustrate these advantages, various embodiments of the new 8T SRAM cell circuit will now be described.

A. Structural Configuration

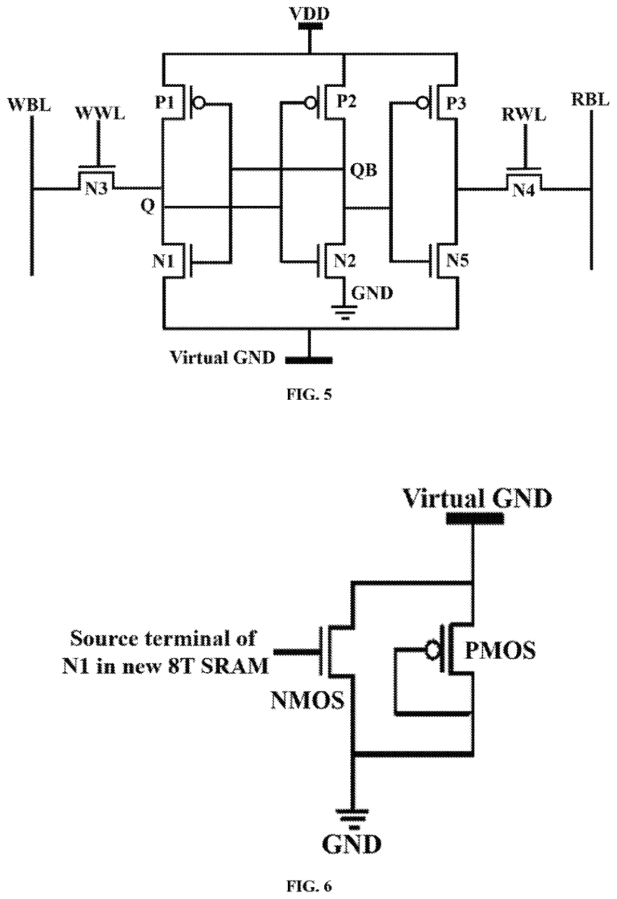

FIG. 5 shows a first embodiment of the 8T SRAM cell circuit of the present invention. The circuit includes a storage cell comprising four transistors P1, P2, N1 and N2 that form a first inverter P1-N1 and a second inverter P2-N2. Transistors P1 and P2 comprise PMOS transistors that function as pull-up transistors, and transistors N1 and N2 comprise NMOS transistors that function as pull-down transistors. Transistors P1 and N1 are connected in series between the supply voltage V_{dd} and a virtual ground node, and transistors P2 and N2 are connected in series between the supply voltage V_{dd} and ground. The input and output terminals of inverters P1-N1 and P2-N2 are cross-coupled such that the output node of inverter P1-N1 is coupled to the input node of inverter P2-N2 to define a first storage node Q and the input node of inverter P1-N1 is coupled to the output node of inverter P2-N2 to define a second storage node QB. The bit stored in the storage cell is accessible via storage nodes Q and QB. Thus, if a “0” is stored in the storage cell, storage node Q is logic low and storage node QB is logic high (i.e., Q=0 and QB=1). If a “1” is stored in the storage cell, storage node Q is logic high and storage node QB is logic low (i.e., Q=1 and QB=0).

The circuit also includes two access transistors N3 and N4. Access transistor N3 is an NMOS transistor that functions as a transfer gate between storage node Q and a write bit line WBL. Access transistor N3 is controlled by a write word line WWL. When write word line WWL is activated, access transistor N3 is turned on so as to couple storage node Q to write bit line WBL. However, when write word line WWL is deactivated, access transistor N3 is turned off so as to decouple storage node Q from write bit line WBL. Similarly, access transistor N4 is an NMOS transistor that functions as a transfer gate between read bit line RBL and storage node QB through a third inverter P3-N5 (discussed below). Access transistor N4 is controlled by a read word line RWL. When read word line RWL is activated, access transistor N4 is turned on so as to couple storage node QB to read bit line RBL. However, when read word line RWL is deactivated, access transistor N4 is turned off so as to decouple storage node QB from read bit line RBL.

The circuit additionally includes a third inverter P3-N5 that includes a pull-up transistor P3 (comprising a PMOS transistor) connected in series with a pull-down transistor N5 (comprising an NMOS transistor) between the supply voltage V_{dd} and the virtual ground node. The third inverter P3-N5 is connected in series between access transistor N4 and storage node QB and is configured to fully charge/discharge read bit line RBL. Thus, a pre-charging circuit is not required. This reduces the area overhead and provides an advantage compared to existing 6T, 7T, 8T and 9T SRAM cells, all of which require pre-charging of the bit lines during the read operation. It should be noted that the charge and discharge powers of the third inverter P3-N5 are only consumed if the readout data is different from the previous state, i.e., the cell consumes no additional power if consecutive 0's or 1's are read out from the storage cell over the read bit line RBL. The transient probability on the read bit line RBL is 50% in a sequence of random data, thereby reducing power consumption during the read operation. As a result, a significant reduction in the power consumption of the memory cell can be achieved so as to provide the robustness and energy efficiency of the 10T SRAM cell circuit described above without the additional area overhead associated with the extra devices and wirings.

New design independent read and write paths allow the use of the minimum sized access transistor N4 for the read operation and a large access transistor N3 for the write operation. In contrast, in the conventional 6T SRAM cell circuit described above, special attention must be given to the size of the access transistors to avoid read upsets. The new 8T SRAM cell circuit offers immunity against such read upsets by employing the third inverter P3-N5 to isolate the storage node QB from the read bit line RBL and, as such, the read out of the bit at storage node QB can be performed without disturbing the stored data. As an example, Table 1 below shows the width of the transistors for the 6T SRAM cell circuit described above compared to the new 8T SRAM cell circuit using 90 nm technology node.

TABLE 1

| | 6T | 8T (New) |
|---|---|---|
| | Width (nm) | Width (nm) |
| Pull-Up Transistors | 90 | 90 |
| Read Access Transistor | 180 | 90 |
| Write Access Transistor | 180 | 135 |
| Pull-Down Transistors | 240 | 180 |

Another advantage of the new 8T SRAM cell circuit is that it uses only one read bit line RBL and one read word line RWL during a read operation and, similarly, uses only one write bit line WBL and one write word line WWL during a write operation. This effectively reduces the power consumption during each of the read and write operations compared to designs that use more than two lines during the read and/or write operations. For example, the 6T SRAM cell circuit described above uses three lines—two bit lines BL and BLB and one word line WL—during each of the read and write operations.

Yet another advantage of the new 8T SRAM cell circuit is that it provides improved read stability and write ability. For example, the 6T SRAM cell circuit described above offers low read stability and write ability in the sub-45 nm region. However, the new 8T SRAM cell circuit offers higher read stability and write ability in the sub-45 nm region.

The new 8T SRAM cell circuit offers many other advantages compared to existing SRAM cell designs, including: (1) reduced total power consumption; (2) reduced area overhead (compared to existing 8T, 9T and 10T SRAM cells); (3) simplified construction and operation and increased response time; (4) improved noise stability and reliability; and (5) use of only a partial circuit during each of the read and write operations. Of course, other advantages will be apparent to one skilled in the art. Table 2 below summarizes various features and attributes of the new 8T SRAM cell circuit in comparison to existing 6T, 7T, 8T, 9T and 10T SRAM cell designs.

TABLE 2

| | | 7T | | | | | |
|---|---|---|---|---|---|---|---|
| | | (Single | | 8T | | | 10T |
| SRAM | | Bit | | (Single- | 8T | | (Single- |
| Design | 6T | Line) | 8T | Ended) | (New) | 9T | Ended) |
| Transistor | 6 | 7 | 8 | 8 | 8 | 9 | 10 |
| Count | | | | | | | |
| Pre-Charging | Yes | Yes | Yes | No | No | Yes | No |
| Circuit | | | | | | | |
| Symmetry | Yes | No | No | Yes | Yes | No | No |
| Active Write | 2 | 1 | 2 | 2 | 1 | 2 | 2 |
| Bit Lines | | | | | | | |

B. Operation

The operation of the new 8T SRAM cell circuit will now be described in connection with its three possible modes: a hold mold, a writing mode, and a reading mode. It is noted that the writing and reading operations are electrically separated to lower power consumption and improve noise margin, as described below.

In the hold mold, write word line WWL is deactivated (i.e., WWL=0) so as to decouple storage node Q from write bit line WBL and, similarly, read word line RWL is deactivated (i.e., RWL=0) so as to decouple storage node QB from read bit line RBL. Thus, the logic will be preserved between the two cross-coupled inverters P1-N1 and P2-N2 so as to hold the current bit in the storage cell.

During a write operation, read word line RWL is deactivated (i.e., RWL=0) so as to turn off access transistor N4 and decouple storage node QB from read bit line RBL. However, write word line WWL is activated (i.e., WWL=1) so as to turn on access transistor N3 and couple storage node Q to write bit line WBL. In addition, a virtual ground circuit is employed to improve the write ability of the cell by weakening the positive feedback of inverters P1-N1 and P2-N2, as described below. During the hold and read operations, the virtual ground node is connected to the ground to retain the stored data in positive feedback. As such, the hold state of the proposed design is similar to that of the 6T SRAM cell described above. However, during the write operation, the virtual ground node is connected to the source of PMOS transistor P1.

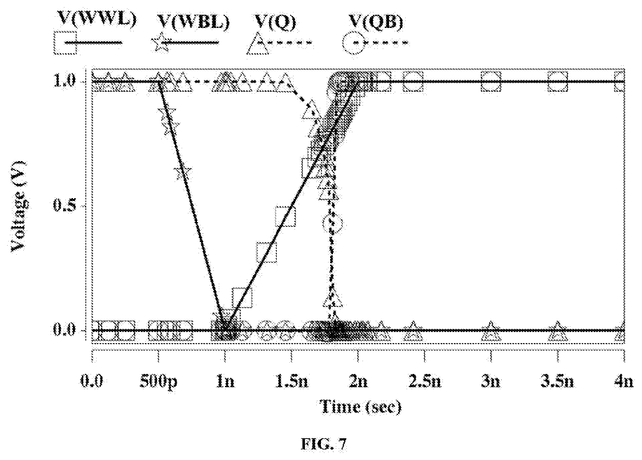

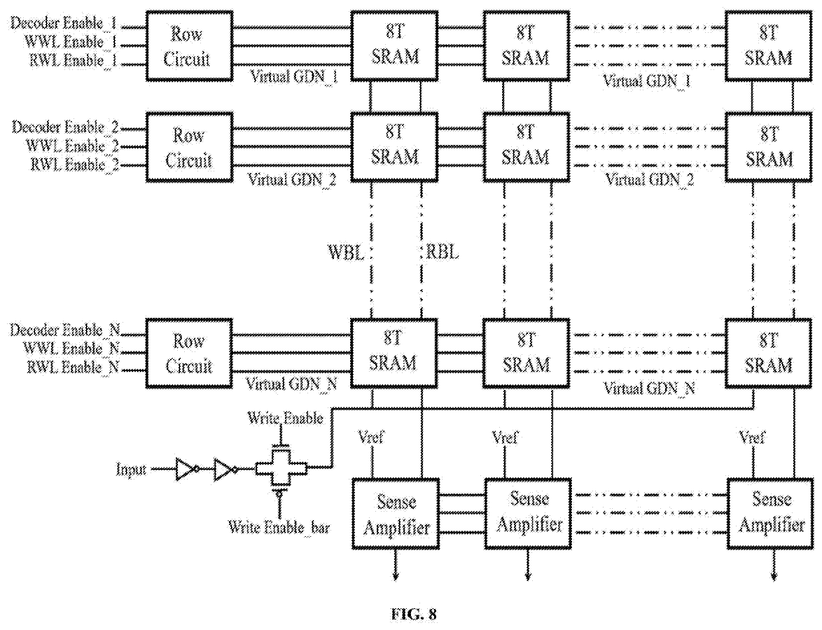

FIG. 6 is a diagram of the virtual ground circuit used in connection with the new 8T SRAM cell shown in FIG. 5 during a write operation. As can be seen, the virtual ground circuit includes an NMOS transistor (labeled “NMOS”) and a PMOS transistor (labeled “PMOS”) as shown. The source of transistor N1 (see FIG. 5) is connected to the gate of the NMOS transistor. Also, the virtual ground node is connected to the source of the PMOS transistor. Since the PMOS transistor is a bad pull-down device, it weakens the positive feedback and the write operation is performed efficiently. For example, let us assume that the storage node Q is initially at “1” and we want to write a “0” into the cell. The write operation initiates once the write word line WWL is active and, then, the write bit line WBL is set to zero in order to write a “0” into the cell. Once the storage node Q falls low, the storage node QB gets high as a nature of positive feedback. FIG. 7 is a plot showing the voltages of the write word line (WWL), the write bit line (WBL), and the two storage nodes (Q and QB) of the 8T SRAM cell circuit shown in FIG. 5 during a write operation.

Preferably, the virtual rails are shared among neighboring SRAM cells to reduce power and area overhead. This sharing of virtual rails can be done in two possible ways: (1) share the rail among SRAM cells in the same row or (2) share the rail among SRAM cells in the same column. It is preferred to share the virtual rails among SRAM cells in the same row because sharing the virtual rails among SRAM cells in the same column suffers from extra power consumption due to leakage and dynamic current in higher activity nodes. FIG. 8 is a diagram of an exemplary memory system architecture of the 8T SRAM cell circuit shown in FIG. 5 in which the virtual rails are shared among SRAM cells in the same row.

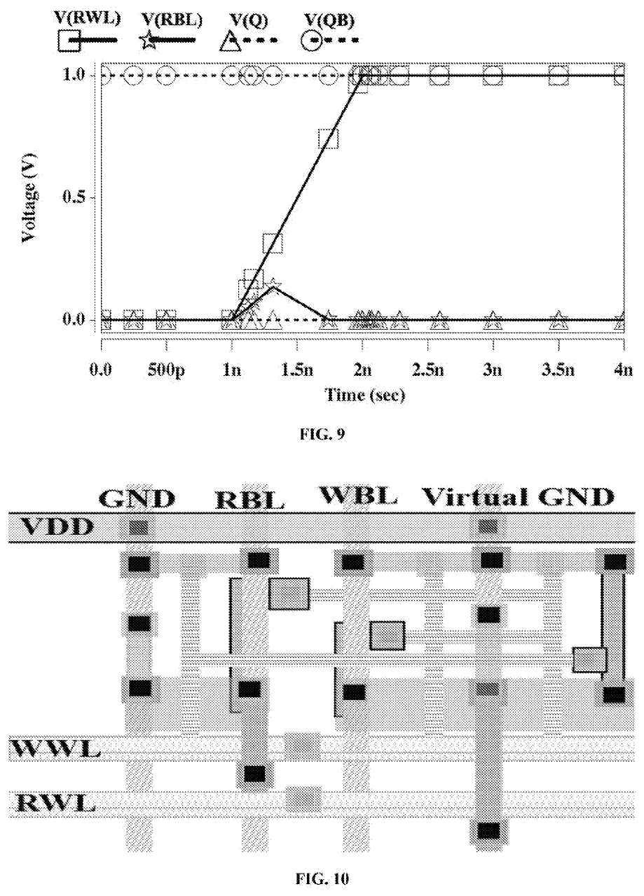

During a read operation, write word line WWL is deactivated (i.e., WWL=0) so as to turn off access transistor N3 and decouple storage node Q from write bit line WBL. However, read word line RWL is activated (i.e., RWL=1) so as to turn on access transistor N4 and couple storage node QB through inverter P3-N5 to read bit line RBL. As such, data stored at storage node QB is fed as input to inverter P3-N5 and transferred through access transistor N4 to read bit line RBL. It can be appreciated that inverter P3-N5 will invert the data transferred to read bit line RBL. As such, an inverter is placed at the end of read bit line RBL to invert the data read out. FIG. 9 is a plot showing the voltages of the read word line (RWL), the read bit line (RBL) and the two storage nodes (Q and QB) of the 8T SRAM cell circuit shown in FIG. 5 during a read operation.

Table 3 below provides a performance summary of the conventional 6T

SRAM cell described above and the new 8T SRAM cell at a 1V supply voltage.

TABLE 3

| SRAM Bitcell | | Conventional 6T | New 8T | Improvement |
|---|---|---|---|---|
| Delay (ps) | Write | 347.2 | 105.3 | 69.67% |
| | Read | 30.13 | 14.2 | 52.87% |
| Power | Write | 18.02 | 16.87 | 6.38% |
| Consumption | Read | 4.37 | 1.82 | 58.35% |
| (nW) | | | | |
| Leakage | Write | 328.6 | 267.3 | 18.65% |
| Current (pA) | Read | 284.8 | 257.8 | 9.5% |
| | Hold | 240.25 | 250.90 | −4.24% |

III. Analysis of Power and Area Overhead

To illustrate the advantages of the new 8T SRAM cell circuit, the power consumption and area overheads of the circuit are compared with those of existing SRAM cell designs.

A. Power Consumption

Existing SRAM cell designs are implemented using different technology nodes from 40 nm technology node to 65 nm technology node. In order to provide a fair comparison of power consumption, all the SRAM cell circuits were tested using 45 nm technology node with a 1 volt supply voltage. Table 4 below provides the data regarding the total power consumption (i.e., read and write operations combined) for the new 8T SRAM cell circuit in comparison to different existing SRAM cells (6T to 10T). This analysis considered only the power consumed by the cell itself and did not add the power consumption of the pre-charging circuits required in existing 6T, 7T, 8T and 9T SRAM cells. Therefore, the actual power consumption during the read operation for the existing 6T, 7T, 8T and 9T SRAM cells would be more than the values shown in Table 4. This data indicates that the new 8T SRAM cell is significantly more energy efficient than all the existing SRAM cell designs both at the individual cell level as well as at the overall memory system level.

TABLE 4

| Design | Write Power (nW) | Read Power (nW) |
|---|---|---|
| Conventional 6T | 18.02 | 4.37 |
| 7T (Single Bit Line) | 15.08 | 4.37 |
| Conventional 8T | 18.02 | 8.75 |
| 8T (New) | 16.87 | 1.82 |
| 9T | 78.63 | 96.24 |
| 9T (SF-SRAM) | 64.03 | 0.96 |
| 10T (Single-Ended) | 87.18 | 17.17 |

B. Area Overhead

In order to calculate the area overhead of the new 8T SRAM cell, the layout was implemented using the 45 nm technology node data available in Cadence Virtuoso Layout Suite. FIG. 10 shows the layout of the new 8T SRAM cell in 45 nm technology node.

Table 5 below provides a comparative analysis of the area overheads of different SRAM cells in 45 nm technology node:

TABLE 5

| Design | Area (μm²) |
|---|---|
| Conventional 6T SRAM | 1.26 × 0.43 |
| Conventional 8T SRAM | 1.55 × 0.41 |
| 10T SRAM | 1.97 × 0.41 |
| 8T SRAM (New) | 1.47 × 0.43 |

With reference to Table 5, the layout and associated area overhead of the conventional 6T SRAM cell was implemented using the 45nm technology node data available in Cadence Virtuoso Layout Suite. The area overhead of the conventional 8T and 10T SRAM cells shown in Table 5 was obtained from published literature, namely, Hiroki Noguchi, Shunsuke Okumura, Yusuke Iguchi, Hidehiro Fujiwara, Yasuhiro Morita, Koji Nii, Hiroshi Kawaguchi, And Masahiko Yoshimoto, “Which Is The Best Dual-Port SRAM In 45-nm Process Technology? 8T, 10T Single End, And 10T Differential,” IEEE International Conference of Integrated Circuit Design and Technology and Tutorial, pp. 55-58, 2008. It is observed that the area overhead of the new 8T SRAM cell increased by 1.16 times compared to the conventional 6T SRAM cell. From the published data, it is observed that the area overhead of the conventional 8T SRAM cell is slightly more than that of the new 8T SRAM cell. However, the area overhead of the 10T SRAM cell is 1.27 times more than the new 8T SRAM cell. Even with the same or slightly higher area overhead, the proposed hybrid design will be significantly more attractive compared to the existing 6T, 7T, 8T, and 9T designs due to its other positive aspects and advantages, such as higher robustness, lower power consumption and more straightforward design and operation as described herein. Overall, the new 8T SRAM cell is better than the 10T SRAM cell design due to lower area overhead and circuit complexity.

IV. Static Noise Margin Analysis

Two of the most critical reliability and robustness metrics of SRAM designs are read stability and write ability. In existing SRAM cell designs, the read margin characterizes the read stability of the SRAM cell and increases with an increase of the sizes of pull-down transistor N1 and access transistor N3. Therefore, a higher cell ratio (CR) leads to a higher read margin. The write margin or the write ability is the minimum voltage on the bit line to flip the data at storage nodes Q and QB and increases with an increase of the sizes of pull-up transistor P2 and access transistor N4. Therefore, a higher pull-up ratio (PR) leads to a higher write margin. The new 8T SRAM cell provides improved stability compared to existing SRAM cell design, as and is analyzed below using two methods: (1) the traditional static noise margin (SNM) method with the butterfly curve and (2) the N-curve method.

A. Static Noise Margin Method

The ability to retain data in the cross-coupled inverters P1-N1 and P2-N2 is expressed as the static noise margin (SNM). SNM is the amount of noise voltage that will flip the data stored at the storage nodes Q and QB. SNM is dependent on the supply voltage (V_{dd}), the cell ratio (CR), and the pull-up ratio (PR). The data retention voltage (DRV) is the minimum V_{dd} required to retain the data at the storage nodes Q and QB in the hold mode when there is no read or write operation. The write-trip point is the maximum voltage on the bit line that flips the stored data. As the value of the write-trip point is decreased, it becomes more difficult to write in the storage cell. The write trip current (WTI) is defined as the current margin of the cell that changes the data stored at the storage node. WTI is inversely proportional to the write-trip point. Therefore, a lower value of WTI allows an easier write in the SRAM cell. With the reduction of V_{dd}, the read operation becomes destructive. At a low V_{dd}, the cell is highly prone to read upset. To minimize the power consumption of the SRAM cell it is recommended to scale down V_{dd}, which lowers the robustness and the speed of the SRAM cell. The SNM degrades with an increase of temperature. The write time of the SRAM cell also decreases with an increase of temperature. Another critical factor that determines the SNM in the SRAM cell is the voltage threshold (Vₜₕ) of the transistors. To improve the SNM, the Vₜₕ of the transistors should be increased. However, a higher Vₜₕ makes the SRAM cell very rigid in terms of operation and change of memory state.

Stability of the cell is a major concern while designing a new SRAM cell. Stability refers to the immunity of a cell against the noise to retain the data at the storage nodes Q and QB. It quantifies the maximum amount of noise voltage that the SRAM cell can withstand without flipping the data at storage nodes Q and QB. The SNM is extracted from the voltage transfer characteristic (VTC) of the two cross-coupled inverters P1-N1 and P2-N2 in the storage cell, which are in positive feedback. The VTC of one of the inverters in the feedback loop is superimposed to the inverse VTC of the other inverter in the loop. The resulting plot is known as the butterfly curve. For SRAM cell reliability analysis, three different SNM figures are relevant: Hold Static Noise Margin (HSNM), Write Static Noise Margin (WSNM) and Read Static Noise Margin (RSNM).

FIG. 11 is a plot showing the HSNM analysis comparison of the new 8T SRAM cell, conventional 6T SRAM cell and conventional 8T SRAM cell for a 1V supply voltage. During the hold mode, the write word line WWL and read word line RWL are deactivated and the access transistors N3 and N4 are turned off. The data is retained at the storage nodes Q and QB. HSNM refers to the stability of the cell during this hold state.

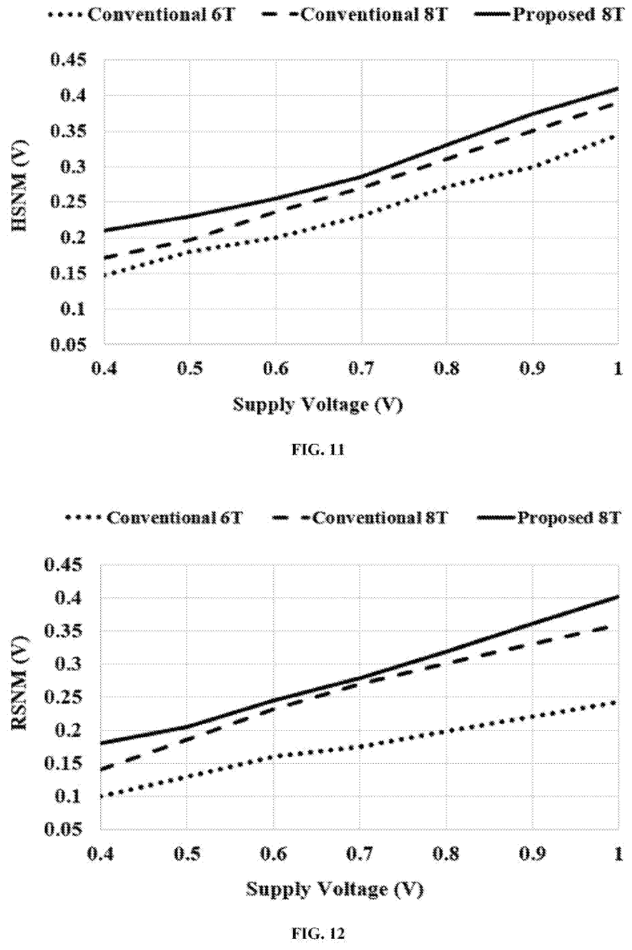

In the conventional 6T SRAM cell described above, RSNM degrades with the scaling down of V_{dd}. By activating the read word line RWL, RSNM can be extracted from the butterfly curve of the cross-coupled inverters P1-N1 and P2-N2 similar to the HSNM. If the external DC noise is greater in magnitude than the SNM, the logic stored in the cell will change. FIG. 12 is a plot showing the RSNM analysis comparison of the new 8T SRAM cell, conventional 6T SRAM cell and conventional 8T SRAM cell for a 1V supply voltage. The RSNM of the new 8T SRAM cell is high for the following reasons: (i) the read bit line RBL is not pre-charged during the read operation and, thus, there is no voltage available on the read bit line RBL to destroy the data at the storage node QB during the read operation; (ii) the inverter P3-N5 isolates the storage node QB from the read bit line RBL and prevents any leakages from the read bit line RBL from disturbing the data at storage node QB; and (iii) the read circuit is separated from the write circuit during the read operation. In contrast, the existing 6T SRAM cell is highly susceptible to noise because the bit lines BL and BLB are pre-charged during the read operation and there is no isolation as in the new 8T SRAM cell design. Very careful selection of the CR and PR values is required to prevent read upset in the 6T SRAM cell.

FIG. 13 is a plot showing the WSNM analysis comparison of the new 8T SRAM cell, conventional 6T SRAM cell and conventional 8T SRAM cell for a 1V supply voltage. The WSNM indicates the write ability of the cell, which is the minimum WBL voltage that flips the data at the storage node of the cell. In the new 8T SRAM design, the write circuit is separated from the read circuit, because each of these two circuits is activated independently by the write word line WWL and the read word line RWL, respectively. The write word line WWL and read word line RWL are not activated together. Additionally, the virtual ground circuit used during the write operation weakens the positive feedback, which further improves the write ability. Therefore, the WSNM of the new 8T SRAM design is very high.

B. N-Curve Method

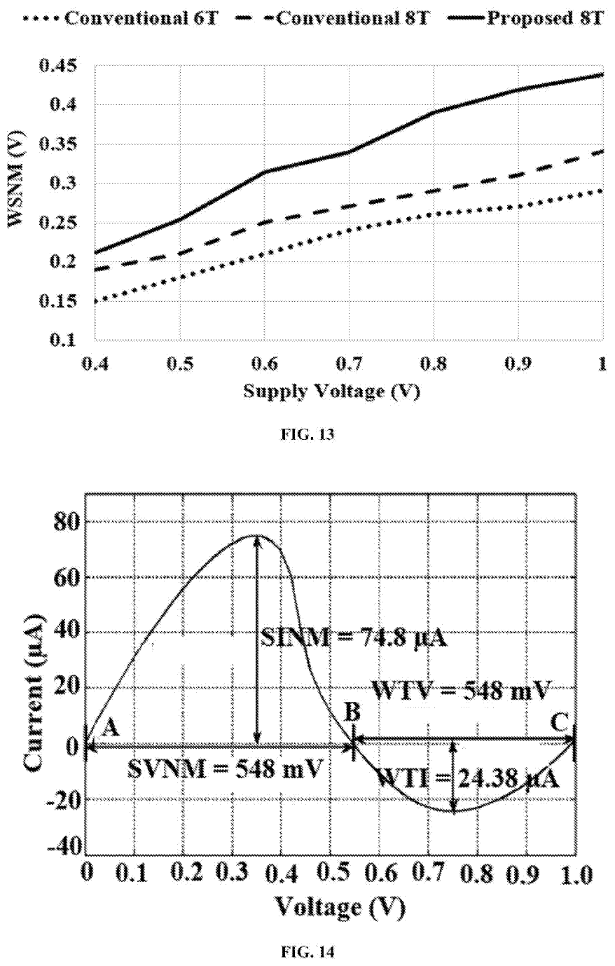

The N-curve method is used to determine the read stability and measure the write ability of a SRAM cell. The N-curve illustrates the stability of the SRAM cell in terms of current. In order to perform this analysis, the new 8T SRAM design is initially set to hold a “0”. DC noise source (Iᵢₙ) is connected to storage node QB of the new 8T SRAM cell. Both the write bit line WBL and the read bit line RBL are clamped to V_{dd}. Then, a DC sweep is performed on storage node QB to get the current waveform through Iᵢₙ. This current curve crosses zero at A, B and C, as shown in FIG. 14.

The part of the current curve between C and B represents write ability. The voltage difference between C and B is defined as the write trip voltage (WTV), which is the voltage required to change the cell data. The negative peak current between C and B is the write trip current (WTI), which is the current margin of the cell that changes the data stored at the storage node. Similarly, the part of the current curve between A and B represents read stability. The static voltage noise margin (SVNM) is the voltage difference between A and B, which is the maximum tolerable DC noise voltage before flipping the content of the cell. The current peak between A and B is the static current noise margin (SINM), which is the maximum current that can be injected in the SRAM cell without flipping the data of the cell.

Table 6 below provides the N-curve parametric details of the conventional 6T SRAM cell and the new 8T SRAM cell.

TABLE 6

| | | | % Improvement of |
|---|---|---|---|
| N-curve | Conventional 6T | New 8T | Write Ability in |
| Metrics | SRAM | SRAM | New 8T SRAM |
| SVNM (mV) | 282 | 548 | 94.33% |
| SINM (μA) | 53.6 | 74.8 | 39.5% |
| WTV (mV) | 718 | 452 | 37.05% |
| WTI (μA) | 96.4 | 24.38 | 74.7% |

V. Analysis of Process and Parametric Variation

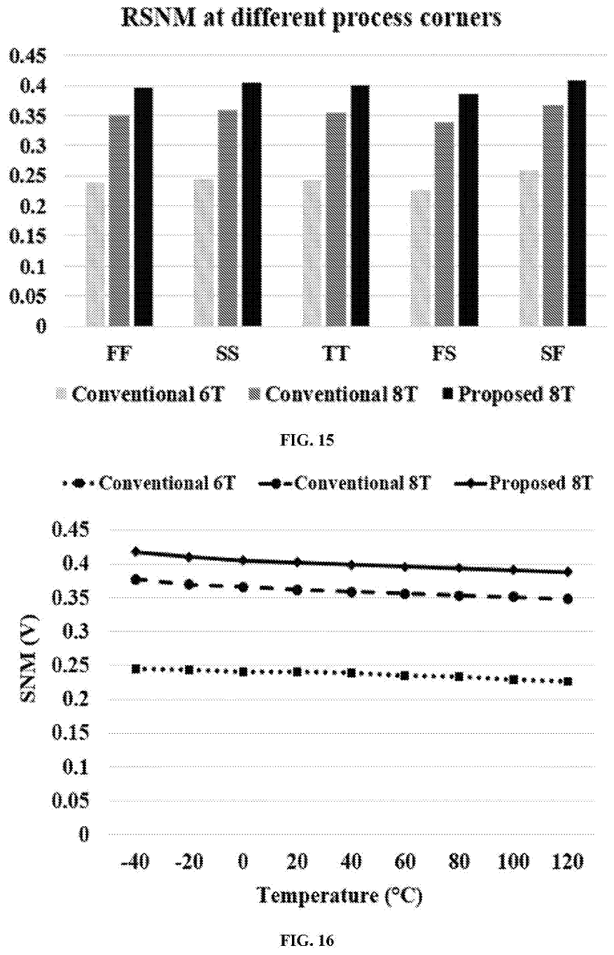

With the shrinking of technologies, supply, process and parametric variations impose a significantly more prominent impact on the performance and reliability of SRAM circuits. Increasing process variations leads to higher failure probability and lower yield in SRAM design. Supply variations due to internal and external causes is a very critical factor. The random dopant fluctuation is one of the primary reasons of memory failure. The inter-die and intra-die variations lead to Vₜₕ mismatch among nearby transistors. Memory dies with low Vₜₕ have a greater probability of read and hold time failures. On the other hand, memory dies with high Vₜₕ have a greater probability of failure during the write operation. Therefore, it is very important for memory design to know the process corners to secure optimum performance and reliability. FIG. 15 shows an RSNM analysis of the new 8T SRAM cell, conventional 6T SRAM cell and conventional 8T SRAM cell at different process corners for 0.4V supply voltage.

Another critical parameter is the temperature, which affects the SNM of SRAM circuits. FIG. 16 shows the variation of the SNM values with temperature in the new 8T SRAM cell, conventional 6T SRAM cell and conventional 8T SRAM cell. It is observed that the stability of the SRAM degrades with an increase of temperature for both the new 8T SRAM cell and the conventional SRAM cells. However, the stability of the new 8T SRAM cell is higher than that of the conventional SRAM cells at any temperature.

VI. Monte Carlo Analysis

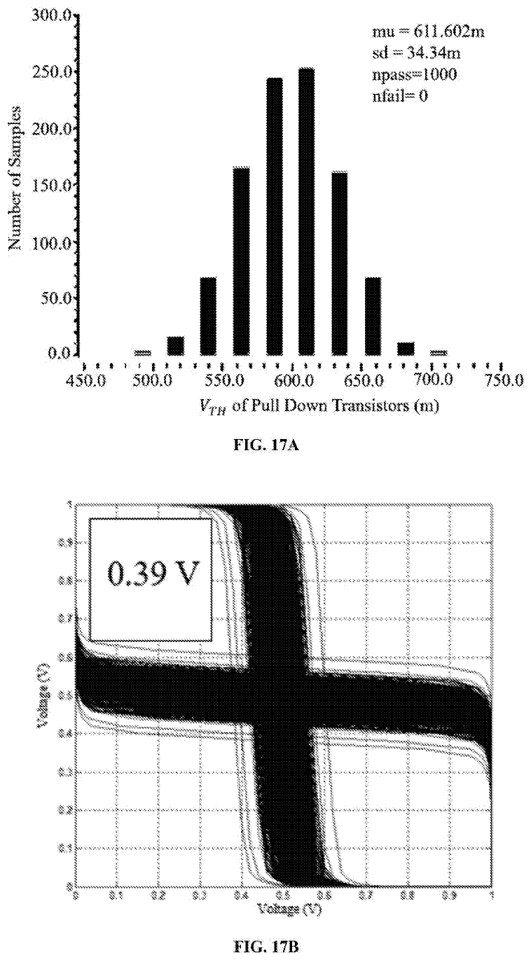

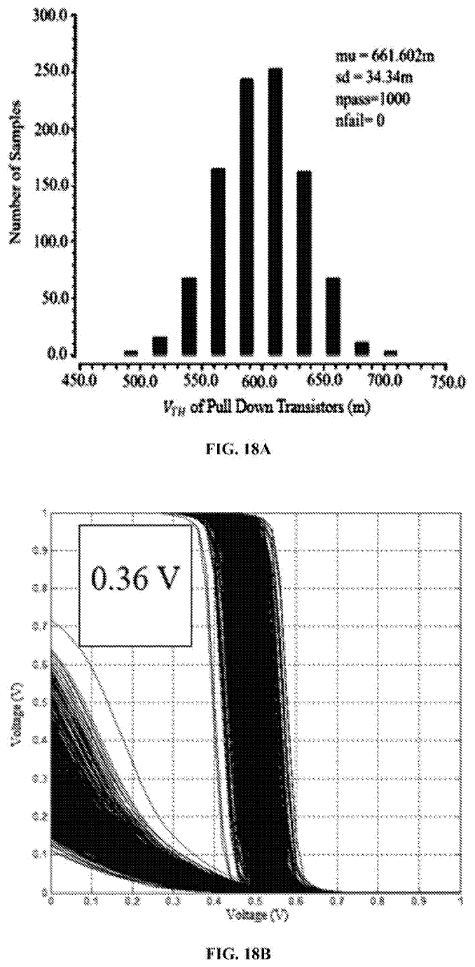

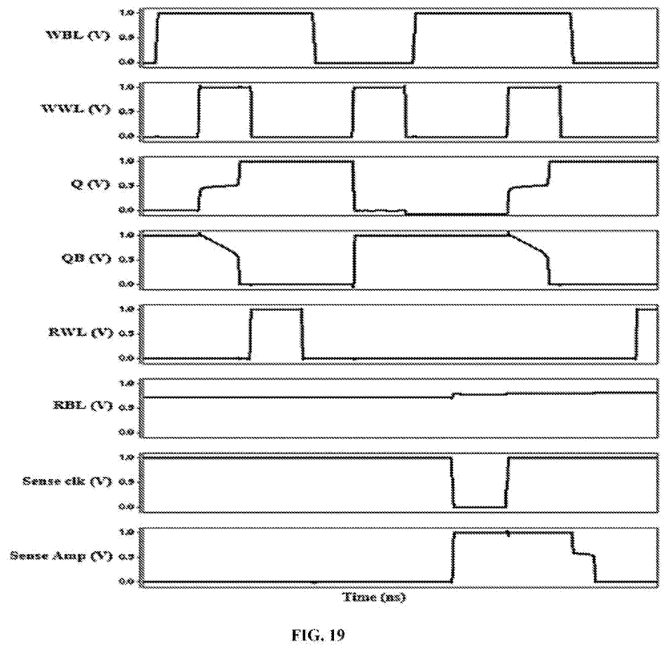

Monte Carlo analysis using statistical models (process and mismatch variation) was carried out to attain a satisfactory SNM with a variation in Vₜₕ. For simulation, the threshold voltage (Vₜₕ) is modeled as a ±10% Gaussian distribution with variation at the ±3σ level. FIGS. 17A and 17B are plots showing the Monte Carlo simulations of the new 8T SRAM cell with 1000 samples at a 1V supply voltage during read. FIGS. 18A and 18B are plots showing the Monte Carlo simulations of the new 8T SRAM cell with 1000 samples at a 1V supply voltage during write. The simulation results show that with process variation, the worst RSNM of the new 8T SRAM cell is 1.62 and 1.05 times better than conventional 6T and 8T SRAM cells, respectively, in the ideal case. Similarly, the worst WSNM of the new 8T SRAM cell is 1.24 and 1.06 times better than the conventional 6T and 8T SRAM cells, respectively, in the ideal case.

VII. Implementation of 1Kb 8T SRAM Array

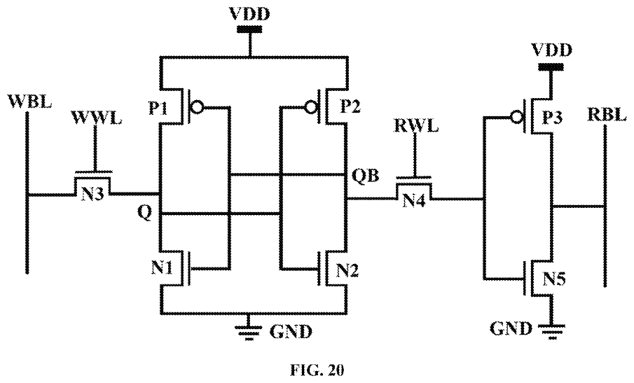

The new 8T SRAM cell design eliminates the pre-charging circuit of the conventional SRAMs because the inverter in the bit cell completely charges/discharges the read bit line RBL. As a result, the power consumption during the read operation and the overall area of the memory system are significantly reduced. FIG. 19 shows the transient response of a 1Kb SRAM array implemented by the new hybrid 8T SRAM cell. To start the write operation, the write bit line WBL is triggered, and once both the write bit line WBL and write word line WWL are high, the value is high at node Q and low at node QB. The values at the nodes Q and QB interchange when the write bit line WBL is low and the write word line WWL is high. The read operation is performed by triggering the read word line RWL. The value at node QB is fed as an input to the inverter P3-N5. The value at node QB is low, and the output of the inverter P3-N5 is high when the read word line RWL is triggered. The output of the inverter P3-N5 gradually charges the read bit line RBL once the read word line RWL is triggered. The area of the new 8T 1Kb SRAM array is only 5.93% more than the conventional 6T 1Kb SRAM array because the proposed 8T SRAM does not require an additional pre-charging circuit and, thus, the overall area of the memory system can be kept low. Moreover, the new 8T SRAM design features a significantly faster access time of 371.8 ps and lower energy consumption of 127.32 pJ/access.

VIII. Alternative Embodiment of New 8T SRAM Cell Circuit

FIG. 20 shows an alternative embodiment of the 8T SRAM cell circuit of the present invention. The circuit includes a storage cell comprising four transistors P1, P2, N1 and N2 that form a first inverter P1-N1 and a second inverter P2-N2. Transistors P1 and P2 comprise PMOS transistors that function as pull-up transistors, and transistors N1 and N2 comprise NMOS transistors that function as pull-down transistors. Transistors P1 and N1 are connected in series between the supply voltage V_{dd} and ground and, similarly, transistors P2 and N2 are connected in series between the supply voltage V_{dd} and ground. The input and output terminals of inverters P1-N1 and P2-N2 are cross-coupled such that the output node of inverter P1-N1 is coupled to the input node of inverter P2-N2 to define a first storage node Q and the input node of inverter P1-N1 is coupled to the output node of inverter P2-N2 to define a second storage node QB. The bit stored in the storage cell is accessible via storage nodes Q and QB. Thus, if a “0” is stored in the storage cell, storage node Q is logic low and storage node QB is logic high (i.e., Q=0 and QB=1). If a “1” is stored in the storage cell, storage node Q is logic high and storage node QB is logic low (i.e., Q=1 and QB=0).

The circuit also includes two access transistors N3 and N4. Access transistor N3 is an NMOS transistor that functions as a transfer gate between storage node Q and a write bit line WBL. Access transistor N3 is controlled by a write word line WWL. When write word line WWL is activated, access transistor N3 is turned on so as to couple storage node Q to write bit line WBL. However, when write word line WWL is deactivated, access transistor N3 is turned off so as to decouple storage node Q from write bit line WBL. Similarly, access transistor N4 is an NMOS transistor that functions as a transfer gate between read bit line RBL and storage node QB through a third inverter P3-N5. Access transistor N4 is controlled by a read word line RWL. When read word line RWL is activated, access transistor N4 is turned on so as to couple storage node QB to read bit line RBL. However, when read word line RWL is deactivated, access transistor N4 is turned off so as to decouple storage node QB from read bit line RBL.

The third inverter P3-N5 includes a pull-up transistor P3 (comprising a PMOS transistor) connected in series with a pull-down transistor N5 (comprising an NMOS transistor) between the supply voltage V_{dd} and ground. The third inverter P3-N5 is connected in series between access transistor N4 and read bit line RBL and is configured to fully charge/discharge read bit line RBL. Thus, a pre-charging circuit is not required, as described above in connection with the first embodiment of the new 8T SRAM cell.

It should be noted that while the 8T SRAM cell circuit shown in FIG. 20 is viable for most operating conditions, the 8T SRAM cell circuit shown in FIG. 5 and described in detail above is more efficient and robust (i.e., all of the data provided above relates to the SRAM cell shown in FIG. 5). Therefore, the 8T SRAM cell circuit shown in FIG. 5 is preferred for use in accordance with the present invention.

IX. General

In this disclosure, the use of any and all examples or exemplary language (e.g., “for example” or “as an example”) is intended merely to better describe the invention and does not pose a limitation on the scope of the invention. No language in the disclosure should be construed as indicating any non-claimed element essential to the practice of the invention.

Also, the use of the terms “comprises,” “comprising,” or any other variation thereof, are intended to cover a non-exclusive inclusion, such that a system, device, circuit or method that comprises a list of elements does not include only those elements, but may include other elements not expressly listed or inherent to such system, device, circuit or method.

In addition, the recitation of ranges of values in this disclosure is merely intended to serve as a shorthand method of referring individually to each separate value falling within the range. Unless otherwise indicated, each individual value is incorporated into the disclosure as if it were individually recited herein.

Further, the use of relative relational terms, such as first and second, are used solely to distinguish one unit or action from another unit or action without necessarily requiring or implying any actual such relationship or order between such units or actions.

Finally, while the present invention has been described and illustrated hereinabove with reference to several embodiments, it should be understood that various modifications could be made to these embodiments without departing from the scope of the invention. Therefore, the present invention is not to be limited to the specific structural configuration or operation of these embodiments, except insofar as such limitations are included in the following claims.

We claim:

1. An 8-transistor (8T) static random access memory (SRAM) cell, comprising:
a first inverter comprising a first pull-up transistor and a first pull-down transistor and a second inverter comprising a second pull-up transistor and a second pull-down transistor, wherein an output node of the first inverter is coupled to an input node of the second inverter to define a first storage node, and wherein an input node of the first inverter is coupled to an output node of the second inverter to define a second storage node;
a third inverter comprising a third pull-up transistor and a third pull-down transistor;
a first access transistor controlled by a write word line, wherein the first access transistor is configured to couple the first storage node to a write bit line when the write word line is activated, and wherein the first access transistor is configured to decouple the first storage node from the write bit line when the write word line is deactivated; and
a second access transistor controlled by a read word line, wherein the second access transistor is configured to couple the second storage node through the third inverter to a read bit line when the read word line is activated, and wherein the second access transistor is configured to decouple the second storage node through the third inverter from the read bit line when the read word line is deactivated.

2. The 8T SRAM cell of claim 1, wherein the third inverter is configured to charge the read bit line.

3. The 8T SRAM cell of claim 2, wherein a pre-charging circuit is not utilized to charge the read bit line.

4. The 8T SRAM cell of claim 1, further comprising a virtual ground circuit configured to weaken the positive feedback of the first and second inverters during a write operation.

5. The 8T SRAM cell of claim 1, wherein only one word line comprising the write word line and only one bit line comprising the write bit line are utilized during the write operation.

6. The 8T SRAM cell of claim 1, wherein only one word line comprising the read word line and only one bit line comprising the read bit line are utilized during a read operation.

7. The 8T SRAM cell of claim 1, wherein the second access transistor is smaller in size than the first access transistor.

8. The 8T SRAM cell of claim 1, wherein the cell is configured to perform a write operation when (i) the write word line is activated so as to turn on the first access transistor and couple the first storage node to the write bit line and (ii) the read word line is deactivated so as to turn off the second access transistor and decouple the second storage node through the third inverter from the read bit line.

9. The 8T SRAM cell of claim 1, wherein the cell is configured to perform a read operation when (i) the read word line is activated so as to turn on the second access transistor and couple the second storage node to the read bit line through the third inverter and (ii) the write word line is deactivated so as to turn off the first access transistor and decouple the first storage node from the write bit line.

10. An 8-transistor (8T) static random access memory (SRAM) cell, comprising:
a first inverter and a second inverter each of which comprises a PMOS transistor and an NMOS transistor, wherein the first and second inverters are cross-coupled to define first and second storage nodes;
a third inverter comprising a PMOS transistor and an NMOS transistor, wherein the third inverter is configured to charge a read bit line;
a first access transistor comprising an NMOS transistor that is controlled by a write word line, wherein the first access transistor is configured to couple the first storage node to a write bit line when the write word line is activated, and wherein the first access transistor is configured to decouple the first storage node from the write bit line when the write word line is deactivated; and
a second access transistor comprising an NMOS transistor that is controlled by a read word line, wherein the second access transistor is configured to couple the second storage node to the read bit line through the third inverter when the read word line is activated, and wherein the second access transistor is configured to decouple the second storage node through the third inverter from the read bit line when the read word line is deactivated.

11. The 8T SRAM cell of claim 10, wherein a write path is utilized during a write operation, wherein the write path is electrically separated from the second access transistor and the third inverter during the write operation, and wherein only one word line comprising the write word line and only one bit line comprising the write bit line are utilized during the write operation.

12. The 8T SRAM cell of claim 11, wherein the cell is configured to perform the write operation when (i) the write word line is activated so as to turn on the first access transistor and couple the first storage node to the write bit line and (ii) the read word line is deactivated so as to turn off the second access transistor and decouple the second storage node through the third inverter from the read bit line.

13. The 8T SRAM cell of claim 10, wherein a read path is utilized during a read operation, wherein the read path is electrically separated from the first access transistor during the read operation, and wherein only one word line comprising the read word line and only one bit line comprising the read bit line are utilized during the read operation.

14. The 8T SRAM cell of claim 13, wherein the cell is configured to perform the read operation when (i) the read word line is activated so as to turn on the second access transistor and couple the second storage node to the read bit line through the third inverter and (ii) the write word line is deactivated so as to turn off the first access transistor and decouple the first storage node from the write bit line.

15. The 8T SRAM cell of claim 10, further comprising a virtual ground circuit configured to weaken the positive feedback of the first and second inverters during a write operation.

16. A static random access memory (SRAM) cell, comprising:
a first inverter and a second inverter that define first and second storage nodes;
a third inverter configured to charge a read bit line;
a first access transistor controlled by a single write word line, wherein the first access transistor is configured to couple the first storage node to a write bit line when the write word line is activated; and
a second access transistor controlled by a single read word line, wherein the second access transistor is configured to couple the second storage node to the read bit line through the third inverter when the read word line is activated.

17. The SRAM cell of claim 16, wherein a write path is utilized during a write operation, and wherein the write path is electrically separated from the second access transistor and the third inverter during the write operation.

18. The SRAM cell of claim 17, wherein the cell is configured to perform the write operation when (i) the single write word line is activated so as to turn on the first access transistor and couple the first storage node to the write bit line and (ii) the single read word line is deactivated so as to turn off the second access transistor and decouple the second storage node through the third inverter from the read bit line.

19. The SRAM cell of claim 16, wherein a read path is utilized during a read operation, and wherein the read path is electrically separated from the first access transistor during the read operation.

20. The SRAM cell of claim 19, wherein the cell is configured to perform the read operation when (i) the single read word line is activated so as to turn on the second access transistor and couple the second storage node to the read bit line through the third inverter and (ii) the single write word line is deactivated so as to turn off the first access transistor and decouple the first storage node from the write bit line.

21. The SRAM cell of claim 16, wherein the second access transistor is smaller in size than the first access transistor.
